(19) United States
(12) Patent Application Publication
(10) Pub. No.: US 2025/0314977 A1
(43) Pub. Date: Oct. 9, 2025

(54) OPTICAL SYSTEM AND LITHOGRAPHY SYSTEM

(71) Applicant: Carl Zeiss SMT GmbH, Oberkochen (DE)

(72) Inventors: Thomas WOLFSTEINER, Aalen (DE); Stefan WALZ, Schwäbisch Gmünd (DE); Markus HOLZ, Aalen (DE); Hermann BIEG, Huettlingen (DE); Andreas-Josef GRIMM, Rainau (DE); Andreas FROMMEYER, Schwäbisch Gmünd (DE)

(21) Appl. No.: 19/246,826

(22) Filed: Jun. 24, 2025

Related U.S. Application Data
(63) Continuation of application No. PCT/EP2024/050529, filed on Jan. 11, 2024.

(30) Foreign Application Priority Data
Jan. 12, 2023 (DE) 10 2023 200 235.3

(51) Int. Cl. G03F 7/00; G02B 19/00

(52) U.S. Cl. CPC G03F 7/70833; G02B 19/0019; G02B 19/0047; G03F 7/70891; G03F 7/70983; G03F 7/70991

(57) ABSTRACT

An optical system for a lithography system comprises: a number of optical elements for guiding radiation; a support device supporting the optical elements; and a plurality of active and/or passive components. The active and/or passive components are arranged on the support device in at least two different planes. The active and/or passive components are arranged on one side of the support device.

### CROSS-REFERENCE TO RELATED APPLICATIONS

The present application is a continuation of, and claims benefit under 35 USC 120 to, international application No. PCT/EP2024/050529, filed Jan. 11, 2024, which claims benefit under 35 USC 119 of German Application No. 10 2023 200 235.3, filed Jan. 12, 2023. The entire disclosure of each of these applications is incorporated by reference herein.

### FIELD

The present disclosure relates to an optical system and to a lithography apparatus having such an optical system.

### BACKGROUND

Microlithography is used to produce microstructured component parts, for example integrated circuits. The microlithography process is performed using a lithography apparatus comprising an illumination system and a projection system. The image of a mask (reticle) illuminated via the illumination system is in this respect projected via the projection system onto a substrate, for example a silicon wafer, that has been coated with a light-sensitive layer (photoresist) and is arranged in the image plane of the projection system, in order to transfer the mask structure to the light-sensitive coating of the substrate.

Driven by the desire for ever smaller structures in the production of integrated circuits, EUV lithography apparatuses which use light at a wavelength in the range of 0.1 nanometer (nm) to 30 nm, for example 13.5 nm, are currently being developed. Since most materials absorb light at this wavelength, such EUV lithography apparatuses usually involve the use of reflective optical units, i.e. mirrors, instead of refractive optical units, i.e. lens elements, as used previously.

The use of what are referred to as MEMS mirrors in an illumination system of a lithography apparatus is known. “MEMS” stands for “micro electro mechanical system”. Such MEMS mirrors comprise an optical element (what is referred to as a micromirror) and an actuator. The actuator makes it possible to change the alignment of the optical element. During operation of the lithography apparatus, working light (for example EUV light) is incident on the surface of the optical element and is reflected there. Changing the alignment of the optical element makes it possible to influence the path taken by the EUV light through the illumination system.

Such MEMS mirrors are generally manufactured on a substrate in integrated fashion, involving only a little structural space. Accordingly, however, there are also often considerable structural space restrictions for electronic components in an area behind the MEMS mirrors, for example on the side facing away from the working light. Additionally, a lot of heat can be given off in this region and is to be regularly discharged in order to reduce or avoid thermal deformations in the region of the MEMS mirror.

### SUMMARY

The present disclosure seeks to provide an improved optical system.

According to a first aspect, an optical system for a lithography apparatus is proposed. The optical system comprises:
a number of optical elements for guiding radiation,
a support apparatus for supporting the optical elements, and
a number N of active and/or passive components,
wherein the active and/or passive components are arranged in at least two different planes on or in the support apparatus.

Arranging the active and/or passive components in the two different planes can result in an improved, for example three-dimensional utilization of the structural space.

For example, it may be provided that the active and/or passive components are arranged in at least two different planes on the support apparatus, the active and/or passive components being arranged on one side of the support apparatus.

These one or more measures can give rise to a high packing density of the active and/or passive components combined with good accessibility for mounting purposes.

In other words, the active and/or passive components are arranged on the same side of the support apparatus. For example, all or only a subset of the active and/or passive components may be arranged on the same side of the support apparatus. In some embodiments, therefore, the active and/or passive components are arranged perpendicularly in relation to a main plane of extent of the support apparatus one behind another, or one above another, on the same side of the support apparatus. This side (with the active and/or passive components in at least two different planes) is for example that side of the support apparatus that faces away from the optical elements. The side can be delimited from the other side (for example with the optical elements) by a continuous material layer of the support apparatus. In other words, the active and/or passive components can lie in at least two different planes to one side of the continuous material layer (for example substrate layer) and the optical elements can lie to the other side of the continuous material layer. The active and/or passive components may be arranged next to and/or directly adjacent to (i.e. in contact with) the support apparatus, for example with the material layer. For example, a first subset of the active and/or passive components may be arranged in a first plane directly adjacent to the support apparatus (or continuous material layer thereof), while a second subset of the active and/or passive components may be arranged in a second plane next to the support apparatus (or continuous material layer thereof) and, if appropriate, indirectly (e.g. with a bridge or a supporting arm positioned in between them) connected thereto. The second subset of the active and/or passive components can be arranged next to the first subset of the active and/or passive components. The first and/or second subset (like the other subsets described above) may for example (each) comprise ≥1, 2, 10 or 100 active and/or passive components.

There may be ≥1, 2, 10 or 100 optical elements. For example, the optical elements are mirrors, for example facet mirrors and/or micromirrors, or lens elements. The radiation that is routed may be, for example, EUV or DUV light.

The (for example each) optical element can be assigned at least one actuator/sensor device (short for “actuator and/or sensor device”), the respective actuator/sensor device being configured to displace the assigned optical element and/or to measure a parameter of the assigned optical element, for example a position of the assigned optical element or a temperature in the region of the assigned optical element.

The (for example each) actuator/sensor device is, for example, an actuating element (or actuator) for actuating an optical element, a sensor for sensing a parameter (for instance the position or temperature) of an optical element or a surrounding area within the optical system, or an actuator and sensor device for actuating and sensing within the optical system. The actuator can be an actuator using the electrostrictive effect or an actuator using the piezoelectric effect, for example a PMN actuator (PMN; lead magnesium niobate) or a PZT actuator (PZT; lead zirconate titanate).

The support apparatus may be in the form of a substrate. The substrate may for example comprise a ceramic, for example comprising aluminum nitride. The support apparatus can support the optical elements. In addition, it may have one or more further functions. For example, the support apparatus may have an electrical connection. For example, the electrical connection may be in the form of a via. One or more of the vias may be arranged such that a vacuum tightness of the support apparatus is ensured (e.g. there are no through-hole vias through the support apparatus, but rather blind vias and/or buried vias). The (for example each) aforementioned actuator/sensor device can be electrically linked up via the electrical connection (via) of the support device. However, the actuator and/or sensor does not absolutely have to be linked up via the support apparatus.

“On the support apparatus” should be understood to the effect that the active and/or passive components are indirectly or directly fastened to the support apparatus. “Indirectly” means fastening, for example electrically contact-connecting, the active and/or passive components with interposition of at least one further element (for example a bridge or a cantilever arm, as described in more detail later on). “Directly” means proximately fastening, for example electrically contact-connecting, the one or more active and/or passive components to the support apparatus, i.e. without interposition of further elements. “In” the support apparatus means that the support apparatus forms an open or closed interior space in which the one or more active and/or passive components are arranged. An example of an open interior space is a pocket formed in one side of the support apparatus. An example of a closed interior space is a closed chamber formed in the support apparatus or a closed housing. The interior space can include—besides the one or more active and/or passive components—a free volume in which a vacuum or ambient pressure (atmospheric pressure) prevails.

The number N of active and/or passive components is ≥1, 2, 5 or 10. The active and/or passive components can also be referred to as active and/or passive component parts, silicon-based elements, electronic components or electronic parts.

The at least two planes may differ from one another in that they are spaced apart in a spatial direction and/or in that they are arranged at an angle, i.e. an angle not equal to 0°, to one another. For example, the planes may be arranged at an angle between 0 up to and including 90° to one another. The respective plane can relate to that region in which the respective active and/or passive component has its electrical connectors for electrical connection to the periphery. The electrical connectors may be in the form of contact points, contact pins, soldering points, SMD (surface mounted device) contact points, and the like. An arrangement of the active and/or the passive components in at least two different planes is therefore not simply the result of these components for instance having different heights. Rather, it is desirable to focus on a height or angular offset between the respective, for example flat contact-connection planes.

According to one embodiment, the at least two different planes are parallel to each other.

In this case, the parallel planes differ in terms of an offset from one another in a direction perpendicular to the two planes.

According to an embodiment, at least two of the active and/or passive components overlap.

The at least two active and/or passive components can overlap as viewed in a direction perpendicular to at least one of the two different planes. Such an overlap can allows particularly high utilization of the structural space.

According to an embodiment, the number of optical elements is arranged on a first (or another, or the other) side of the support apparatus.

In the present case, the first side is also referred to as “front side”. This is the support-apparatus side that faces toward the radiation (working light).

According to an embodiment, at least one subset of the active and/or passive components is arranged on a second (or the one) side of the support apparatus, on or underneath a bridge arranged on the second (or the one) side of the support apparatus, on or underneath a cantilever arm arranged on the second (or the one) side of the support apparatus, or in an interior space of the support apparatus.

The second (or the one) side may be a back side of the support apparatus. “Back side” means a side situated opposite and facing away from the front side. In some embodiments, the second side could also be a support-apparatus side perpendicular to the front side or arranged at a different angle.

“On” the bridge means that the one or more active and/or passive components may be arranged on any portion of the bridge, whether on its pillars or on the spanning portion. “Underneath” means that the one or more active and/or passive components are arranged underneath the spanning portion of the bridge on the second side of the support apparatus. In other words, the spanning portion of the bridge overlaps the corresponding active and/or passive component, or coincides with it (when the bridge is viewed from above).

The cantilever arm can have a foot portion with which it is braced against the second side of the support apparatus. The opposite, i.e. other, end of the cantilever arm is free. In the present case, “on” the cantilever arm means that the one or more active and/or passive components may be arranged on any portion of the cantilever arm, whether on its foot portion or on its self-supporting portion. “Underneath” means that the one or more active and/or passive components are arranged underneath the self-supporting portion of the cantilever arm on the second side of the support apparatus. In other words, the self-supporting portion of the cantilever arm overlaps the corresponding active and/or passive component, or coincides with it (when the cantilever arm is viewed from above).

The “interior space” includes open and closed interior spaces. The interior space may also be partially closed.

According to an embodiment, at least one subset of the active and/or passive components is arranged on a top side of the bridge or of the cantilever arm and/or on a bottom side of the bridge or of the cantilever arm.

The “top side” of the bridge means the bridge side that faces away from the second side of the support apparatus; the bottom side of the bridge means the bridge side that faces toward the second side of the support apparatus. The same applies for the cantilever arm.

According to an embodiment, a first active and/or passive component is arranged on the bridge or the cantilever arm and a second active and/or passive component is arranged underneath the bridge or the cantilever arm.

This can help afford an especially compact design.

According to an embodiment, the support apparatus is made of a composite material forming at least one housing, the housing containing at least one of the active and/or passive components.

This measure can also help afford an especially compact design.

According to an embodiment, a first subset N1 of the active and/or passive components is arranged on the second (or the one) side of the support apparatus, a second subset N2 of the active and/or passive components is arranged on or underneath a bridge arranged on the second (or the one) side of the support apparatus or on or underneath a cantilever arm arranged on the second (or the one) side of the support apparatus, and a third subset N3 of the active and/or passive components is arranged in an interior space of the support apparatus, where it can be the case that N=N1+N2+N3.

According to an embodiment, the bridge or the cantilever arm is made of a ceramic.

The ceramic may for example comprise aluminum nitride. The bridge and/or the cantilever arm may be manufactured with the support apparatus in integrated fashion. This means methods for manufacturing microelectronics, for instance vapor deposition methods, for manufacturing for example a corresponding layer structure.

According to an embodiment, the N active and/or passive components comprise an integrated circuit, a processor, a microprocessor, an FPGA, an analog-to-digital converter, a digital-to-analog converter, a transistor, more particularly a MOSFET, a capacitor, a resistor, an inductor and/or a contact-connection device, more particularly a plug or a socket.

The contact-connection device is for example configured for the contact connection of a circuit board or is electrically connected to a circuit board.

The circuit board can comprise conductor tracks in an electrically insulating material. The conductor tracks may be embedded in and/or adhere to the electrically insulating material. As explained in more detail later on, one or more active and/or passive components may be provided on or in the circuit board. The circuit board can serve to mechanically fasten and electrically link up these electronic components. The electrically insulating material may be, for instance, a fiber-reinforced plastic, hard paper and/or a (for example sintered) ceramic. The conductor tracks may be etched out of a thin layer of copper. The electronic components may be soldered or pressed onto soldering pads or into soldering lands of the circuit board.

The circuit board may be rigid and/or flexible. For example, the circuit board may be installed in the optical system in a warped state. To this end, the circuit board may for instance be in the form of a rigid-flex board or flex board with or without a stiffening element. This can be desirable as regards the prevalent structural space restrictions.

The circuit board may be made of a composite material. For example, the circuit board comprises a plurality K of plies that form the composite material and comprise two external plies and a plurality M of internal plies arranged between the two external plies, it being possible for example for a housing to be formed in the region of the M internal plies. In some embodiments, the M internal plies are formed by an alternating sequence of metal layers and insulator layers. For example, the metal layers are made of copper. For example, the insulator layers are made of a glass-fiber substrate and/or an epoxy resin. For example, the external plies are in the form of metal layers suitable for dissipating heat. The respective external ply or layer can also be in the form of an insulation layer, such as an outgassing-resistant plastics film, or a lacquer.

The circuit board may be sheet-like. For example, a thickness of the circuit board may be less than 1 centimeter (cm), less than 0.5 cm or less than 0.3 cm. The circuit board may also have a different geometry. For example, the circuit board may be in the form of a bar and/or be designed with a rectangular, circular or other cross section.

The circuit board may extend for example perpendicularly in relation to the main plane of extent of the support apparatus. In the present case, “perpendicular(ly)” also includes deviations of up to 20°, such as up to 10°, for example up to 5°, from the exact perpendicular.

The circuit board can be or is electrically connected, for example at its one end, to the contact-connection device (in the present case also “first” contact-connection device). At its other, for example opposite end, the circuit board may be electrically connectable or electrically connected to a further contact-connection device (in the following text also “second” contact-connection device).

According to an embodiment, the contact-connection device can be electrically connected to the circuit board, the contact-connection device being arranged on the bridge or on the cantilever arm.

This can help establish a structural-space-saving electrical connection between a circuit board and the support apparatus.

According to one embodiment, the circuit board can be electrically connected detachably to the contact-connection device.

Correspondingly, the circuit board can be easily replaced when it has a defect.

According to an embodiment, the contact-connection device is in the form of a socket or a plug.

Such plug-in connectors can be connected easily. For example, the circuit board may have a circuit board connector, also referred to as card-edge connector, peripheral connector or edge connector.

According to an embodiment, the contact-connection device has a number of springs and/or spring contact pins or contact points that can be contacted thereby.

The one or more springs (or spring contact pins) can help secure the electrical contact via a resiliently applied pressure or frictional engagement. Such contact points may be referred to as “landing pads”. For example, the springs and/or spring contact pins may be attached to the circuit board and the contact points may be attached to the support apparatus, or vice versa. The former can have the feature that, if one or more of the springs or spring contact pins fails, the circuit board including the one or more failed springs or pins can be easily replaced.

According to an embodiment, the contact-connection device has a one-piece interface.

This type of contact-connection device, in general, only takes up a little structural space and has high reliability. The one-piece interface can be in the form of an insert part and/or soldered to the circuit board or the support apparatus.

According to an embodiment, the circuit board has a number of active and/or passive components and/or can be electrically connected thereto.

The active or passive components can be provided, for example mounted, on or in the circuit board. There may be ≥1, 2, 5 or 10 active or passive components. In the present case, “mounting” can include for instance soldering or adhesive bonding with a conductive adhesive.

According to an embodiment, the optical system comprises a housing apparatus, the housing apparatus optionally being thermally conductively connected to at least one of the active and/or passive components.

This can help make it possible to efficiently discharge the heat which accumulates.

On the back side of the support apparatus, a number of active and/or passive components may be arranged, or mounted. They may be thermally conductively coupled to the housing apparatus, for example to its end face. For improved thermal conduction, a thermally conductive material (referred to as TIM—“thermal interface material”), for example a thermally conductive paste, may be provided between each active and/or passive component and the housing apparatus.

According to an embodiment, the housing apparatus is connected, for example indirectly or directly, to the support apparatus.

The housing apparatus can be made of a thermally conductive material, such as copper or aluminum or alloys thereof. A high-alloy steel or a ceramic can also be considered.

According to an embodiment, the circuit board is routed through the housing apparatus.

In some embodiments, the circuit board extends partially or completely through a cavity formed by the housing apparatus. Within the cavity, the housing apparatus may have brace portions which brace the circuit board. The housing apparatus may be designed for example to protect the circuit board against external actions of force.

According to an embodiment, a gap between the housing apparatus and the at least one active and/or passive component is filled with a thermally conductive material.

This can help make it possible to improve the heat dissipation. It also can help make it possible to simplify the mounting.

According to an embodiment, a gap between the bridge or the cantilever arm and at least one of the active and/or passive components is filled with a thermally conductive material.

As an alternative or in addition, a gap between the bridge or the cantilever arm and the support apparatus and/or the housing apparatus can be filled with a thermally conductive material.

According to an embodiment, the thermally conductive material is a thermally conductive paste.

This can help make it possible to efficiently compensate for an offset between components. At the same time, a high transfer of heat is ensured.

In embodiments, a number of active and/or passive components arranged on the circuit board is thermally conductively connected to the housing apparatus. This can also be realized using a thermally conductive material, for example a thermally conductive paste. The thermally conductive material for example is provided in, or fills, a gap between one of the number of passive and/or active components and the housing apparatus.

According to an embodiment, the housing apparatus has a cylindrical shape, which is connected on its one end face to the support apparatus.

For example, the cylindrical shape may have a round, rectangular, oval or other cross section. The end face of the cylindrical shape may be plugged in the support apparatus and/or adhesively bonded or soldered thereto.

According to an embodiment, at least one heat tube extends through the housing apparatus.

This can help make it possible to discharge heat from the support apparatus, for example toward a cooling apparatus. In the present case, a “heat tube” is understood to mean a heat exchanger which uses enthalpy of evaporation of a medium to allow a high heat flow density. The heat tube can for example be in the form of a heat pipe or two-phase thermosiphon. In addition or as an alternative, the outside, for example the lateral surface, of the housing apparatus, for example the cylindrical shape, can be cooled. For this, for example, a coolant can flow around the housing apparatus, for example in a duct. The coolant under consideration is, for example, water or air. The duct may be integrated in a cooling apparatus surrounding the housing apparatus or may adjoin the lateral surface directly, i.e. outright, with the result that the coolant flows directly along the lateral surface.

According to an embodiment, the circuit board forms a housing which contains a number of active and/or passive components.

The housing may be vacuum-tight. The housing may be formed in an interior region of the circuit board. Embedding the vacuum-tight housing in the interior region of the circuit board also allows the active and/or passive components to be accommodated in the vacuum housing of the optical system without being influenced by the adjacent/surrounding vacuum. The composite material (and/or a ceramic) of the printed circuit board for example forms the vacuum-tight housing, which encapsulates the number of active and/or passive component parts, for example in full and void of air.

According to an embodiment, the number of optical elements, the support apparatus and the circuit boards form a premountable or premounted unit, which can be or is mounted on a holding apparatus.

This can help make it easier to mount the optical system, for example when multiple such premounted units are formed. The holding apparatus may for example be a cooling apparatus for cooling the premountable unit(s) and/or a current and/or voltage supply apparatus for supplying current and/or voltage to the premounted unit(s).

According to an embodiment, the optical system has a plurality J of devices, each device having a respective number of optical elements, a respective support apparatus and a respective circuit board.

This results in a modular design which can be mounted and serviced conveniently. J is≥2, such as ≥5, for example ≥10.

According to an embodiment, the optical system has a holding apparatus, the J devices being pluggable into or plugged in the holding apparatus.

The holding apparatus may for example, as described above, be in the form of a cooling apparatus and/or a current and/or voltage supply apparatus. The J devices may also be fastenable or fastened on or in the holding apparatus in another way (instead of being plugged in).

Such a cooling apparatus may comprise a mechanism for discharging heat from a respective housing apparatus of the J devices. For example, heat is discharged by the at least one heat tube of the respective housing apparatus. For example, the holding apparatus may have cylindrical openings into which the J devices can be plugged. Each cylindrical opening may have an for example circular, rectangular, oval or other cross section.

According to an embodiment, the optical system comprises a vacuum housing which contains the number of optical elements. For example, the vacuum housing is designed for a pressure of 1013.25 hPa to 10⁻³ hPa, such as 10⁻³ to 10⁻⁸ hPa, for example 10⁻⁸ to 10⁻¹¹ hPa, in its interior space. In some embodiments, the support apparatus, the circuit board and/or the housing apparatus may also be arranged in the vacuum. In other embodiments, the optical system has a housing which contains the number of optical elements and in which an excess pressure prevails.

According to an embodiment, the optical system is in the form of an illumination optical unit or a projection optical unit of the lithography apparatus.

According to a second aspect, a lithography apparatus, for example an EUV or DUV lithography apparatus, comprising an optical system as described herein is provided.

The lithography apparatus or projection exposure apparatus may be an EUV lithography apparatus. EUV stands for “extreme ultraviolet” and denotes a wavelength of the working light of between 0.1 nm and 30 nm. The lithography apparatus or projection exposure apparatus may also be a DUV lithography apparatus. DUV stands for “deep ultraviolet” and denotes a wavelength of the working light of between 30 nm and 250 nm.

According to a third aspect, a method for producing an optical system for a lithography apparatus is provided, the method comprising:
a) providing a number of optical elements on a support apparatus;
b) providing at least two active and/or passive components in different planes on or in the support apparatus, one of the passive and/or active components optionally being a contact-connection device; and optionally
c) electrically connecting a circuit board to the contact-connection device.

The list items a), b) and c) do not imply a sequence of the method steps. Rather, they can also be performed in another sequence, for example step a) after step b).

According to one embodiment, the method also comprises:
premounting the number of optical elements, the support apparatus, the at least two active and/or passive components and/or the circuit board to form a premounted unit; and
mounting the premounted unit on a holding apparatus.

This can help make the mounting easier.

According to a further aspect, an optical system for a lithography apparatus is provided, comprising:
a number of optical elements for guiding radiation,
a support apparatus for supporting the optical elements, and
a number N of active and/or passive components,
wherein the active and/or passive components are arranged in at least two different planes in the support apparatus,
wherein at least one subset of the active and/or passive components is arranged in a closed interior space of the support apparatus, the closed interior space being a closed chamber or a closed housing.

This measure can give rise to a high packing density of the active and/or passive components combined with good accessibility for mounting purposes.

The features, refinements and aspects described for the first aspect apply, mutatis mutandis, to the other aspects, and vice versa.

“A” or “an” in the present context should not necessarily be regarded as a restriction to exactly one element. Instead, multiple elements, for example two, three or more, may also be provided. Any other numeral used here should also not be understood as a restriction to exactly the stated number of elements. Rather, unless indicated to the contrary, numerical upward and downward deviations are possible. A “second” element does not necessarily presuppose a “first” element.

Further possible implementations of the disclosure also comprise combinations which were not mentioned explicitly of features or embodiments described above or hereinafter with respect to the exemplary embodiments. A person skilled in the art will also add individual aspects as improvements or supplementations to the respective basic form of the disclosure.

Further features, configurations and aspects of the disclosure are the subject of the dependent claims and of the exemplary embodiments of the disclosure that are described hereinafter. The disclosure is explained in detail in the following text on the basis of certain embodiments with reference to the accompanying figures.

### BRIEF DESCRIPTION OF THE DRAWINGS

FIG. 1 shows a schematic meridional section of a projection exposure apparatus for EUV projection lithography.

FIG. 2 shows a sectional view of a first embodiment of an optical system.

FIG. 3 shows a schematic illustration, in perspective, of a second embodiment of an optical system.

FIG. 4 shows a perspective view of a circuit board according to one embodiment.

FIG. 5 schematically shows a detail of a contact connection of the circuit board via a contact-connection island, according to one embodiment.

FIG. 6 also schematically shows a detail of a variant for contact connection of the circuit board, in this case using springs according to one embodiment.

FIG. 7 shows a sectional view of a detail of a region VII from FIG. 2 according to one variant.

FIG. 8 shows a sectional view of a region of a printed circuit board with a housing formed inside it, according to one embodiment.

FIG. 9 shows a perspective view of a contact-connection device on a bridge on the basis of the exemplary embodiment from FIG. 2.

FIG. 10 schematically shows various possible variants for the arrangement of active and/or passive components on or underneath a bridge or a cantilever arm.

FIG. 11 shows a partial section through a support apparatus according to one embodiment.

FIG. 12 shows a flow diagram of a method according to one embodiment.

### DETAILED DESCRIPTION

Unless indicated to the contrary, elements that are identical or functionally identical have been provided with the same reference signs in the figures. It should also be noted that the representations in the figures are not necessarily true to scale.

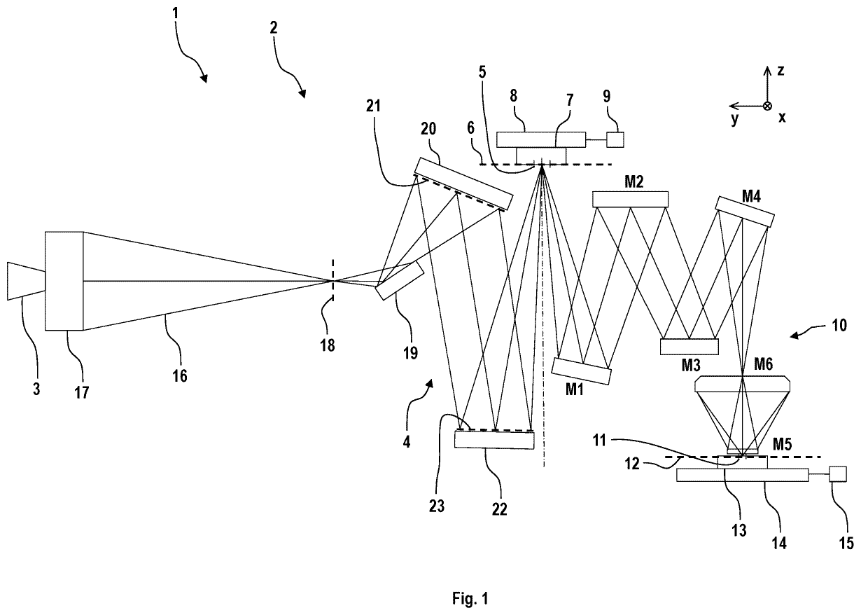

FIG. 1 shows one embodiment of a projection exposure apparatus 1 (lithography apparatus), for example an EUV lithography apparatus. In addition to a light source or radiation source 3, an embodiment of an illumination system 2 of the projection exposure apparatus 1 has an illumination optical unit 4 for illuminating an object field 5 in an object plane 6. In an alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 shows, by way of illustration, a Cartesian coordinate system with an x-direction x, a y-direction y, and a z-direction z. The x-direction x runs perpendicularly into the plane of the drawing. The y-direction y runs horizontally, and the z-direction z runs vertically. The scanning direction runs along the y-direction y in FIG. 1. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 runs parallel to the object plane 6. As an alternative, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction y. The displacement on the one hand of the reticle 7 by way of the reticle displacement drive 9 and on the other hand of the wafer 13 by way of the wafer displacement drive 15 may take place in such a way as to be synchronized with one another.

The light source 3 is an EUV radiation source. The light source 3 emits for example EUV radiation 16, which is also referred to below as used radiation, illumination radiation or illumination light. The used radiation 16 has for example a wavelength in the range of between 5 nm and 30 nm. The light source 3 can be a plasma source, for example an LPP (short for: laser produced plasma) source or a DPP (short for: gas-discharge produced plasma) source. It may also be a synchrotron-based radiation source. The light source 3 can be an FEL (short for: free-electron laser).

The illumination radiation 16 emanating from the light source 3 is focused by a collector 17. The collector 17 may be a collector with one or more ellipsoidal and/or hyperboloidal reflection surfaces. The illumination radiation 16 may be incident on the at least one reflection surface of the collector 17 with grazing incidence (GI), i.e. at angles of incidence of greater than 45°, or with normal incidence (NI), i.e. at angles of incidence of less than 45°. The collector 17 may be structured and/or coated on the one hand for optimizing its reflectivity for the used radiation and on the other hand for suppressing extraneous light.

Downstream of the collector 17, the illumination radiation 16 propagates through an intermediate focus in an intermediate focal plane 18. The intermediate focal plane 18 can represent a separation between a radiation source module, comprising the light source 3 and the collector 17, and the illumination optics unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect that goes beyond the purely deflecting effect. As an alternative or in addition, the deflection mirror 19 may be in the form of a spectral filter that separates a used light wavelength of the illumination radiation 16 from extraneous light of a wavelength deviating therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which can also be referred to as field facets. Only some of these first facets 21 are illustrated in FIG. 1 by way of example.

The first facets 21 can be embodied as macroscopic facets, for example as rectangular facets or as facets with an arcuate or an edge contour of part of a circle. The first facets 21 can be in the form of plane facets or alternatively as facets with convex or concave curvature.

As is known for example from DE 10 2008 009 600 A1, the first facets 21 themselves may each also be composed of a multiplicity of individual mirrors, for example a multiplicity of micromirrors. The first facet mirror 20 may for example be in the form of a microelectromechanical system (MEMS system). For details, reference is made to DE 10 2008 009 600 A1.

The illumination radiation 16 travels horizontally, i.e. along the y-direction y, between the collector 17 and the deflection mirror 19.

In the beam path of the illumination optical unit 4, a second facet mirror 22 is arranged downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal boundary, or alternatively may be facets composed of micromirrors. In this regard, reference is likewise made to DE 10 2008 009 600 A1.

The second facets 23 may have plane reflection surfaces or alternatively reflection surfaces with convex or concave curvature.

The illumination optical unit 4 thus forms a doubly faceted system. This fundamental principle is also referred to as a fly's eye condenser (or fly's eye integrator).

It may be desirable to arrange the second facet mirror 22 not exactly in a plane that is optically conjugate to a pupil plane of the projection optical unit 10. For example, the second facet mirror 22 may be arranged so as to be tilted in relation to a pupil plane of the projection optical unit 10, as described for example in DE 10 2017 220 586 A1.

The second facet mirror 22 is used to image the individual first facets 21 into the object field 5. The second facet mirror 22 is the last beam-shaping mirror or actually the last mirror for the illumination radiation 16 in the beam path upstream of the object field 5.

In a further embodiment (not illustrated) of the illumination optical unit 4, a transfer optical unit contributing for example to the imaging of the first facets 21 into the object field 5 can be arranged in the beam path between the second facet mirror 22 and the object field 5. The transfer optical unit can have exactly one mirror or alternatively two or more mirrors, which are arranged one behind another in the beam path of the illumination optical unit 4. The transfer optical unit can for example comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In a further embodiment of the illumination optical unit 4, the deflection mirror 19 may also be omitted, and so the illumination optical unit 4 may then have exactly two mirrors downstream of the collector 17, specifically the first facet mirror 20 and the second facet mirror 22.

The imaging of the first facets 21 into the object plane 6 via the second facets 23 or using the second facets 23 and a transfer optics unit is often only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optics unit 10 comprises six mirrors M1 to M6. Alternatives with four, eight, ten, twelve or a different number of mirrors Mi are also possible. The projection optical unit 10 is a twice-obscured optical unit. The penultimate mirror M5 and the last mirror M6 each have a through opening for the illumination radiation 16. The projection optical unit 10 has an image-side numerical aperture that is greater than 0.5 and may also be greater than 0.6, and may be for example 0.7 or 0.75.

Reflection surfaces of the mirrors Mi may take the form of free-form surfaces without an axis of rotational symmetry. Alternatively, the reflection surfaces of the mirrors Mi may be designed as aspheric surfaces with exactly one axis of rotational symmetry of the reflection surface shape. Just like the mirrors of the illumination optical unit 4, the mirrors Mi may have highly reflective coatings for the illumination radiation 16. These coatings may be designed as multilayer coatings, for example with alternating layers of molybdenum and silicon.

The projection optical unit 10 has a large object-image offset in the y-direction y between a y-coordinate of a center of the object field 5 and a y-coordinate of the center of the image field 11. This object-image offset in the y-direction y can be of approximately the same magnitude as a z-distance between the object plane 6 and the image plane 12.

The projection optical unit 10 may for example have an anamorphic form. It has for example different imaging scales βx, βy in the x- and y-directions x, y. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, i.e. in a direction perpendicular to the scanning direction.

The projection optical unit 10 leads to a reduction in size of 8:1 in the y-direction y, i.e. in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 can be the same or can differ, depending on the embodiment of the projection optical unit 10. Examples of projection optical units with different numbers of such intermediate images in the x-direction x and y-direction y are known from US 2018/0074303 A1.

In each case, one of the second facets 23 is assigned to exactly one of the first facets 21 for forming in each case an illumination channel for illuminating the object field 5. This may for example produce illumination according to the Köhler principle. The far field is decomposed into a multiplicity of object fields 5 with the aid of the first facets 21. The first facets 21 create a plurality of images of the intermediate focus on the second facets 23 respectively assigned to them.

By way of an assigned second facet 23, the first facets 21 are each imaged onto the reticle 7 and overlaid on one another for the purpose of illuminating the object field 5. The illumination of the object field 5 is for example as homogeneous as possible. It can have a uniformity error of less than 2%. The field uniformity may be achieved by way of the overlay of different illumination channels.

The illumination of the entrance pupil of the projection optical unit 10 can be defined geometrically by an arrangement of the second facets 23. The intensity distribution in the entrance pupil of the projection optical unit 10 can be set by selecting the illumination channels, for example the subset of the second facets 23, which guide light. This intensity distribution is also referred to as illumination setting or illumination pupil filling.

A likewise preferred pupil uniformity in the region of portions of an illumination pupil of the illumination optical unit 4 which are illuminated in a defined manner may be achieved by a redistribution of the illumination channels.

Further aspects and details of the illumination of the object field 5 and for example of the entrance pupil of the projection optical unit 10 are described below.

The projection optical unit 10 may have for example a homocentric entrance pupil. The latter may be accessible. It may also be inaccessible.

The entrance pupil of the projection optical unit 10 frequently cannot be exactly illuminated with the second facet mirror 22. When imaging the projection optical unit 10, which images the center of the second facet mirror 22 telecentrically onto the wafer 13, the aperture rays often do not intersect at a single point. However, it is possible to find an area in which the spacing of the aperture rays that is determined in pairs becomes minimal. This area represents the entrance pupil or an area in real space conjugate thereto. For example, this area has a finite curvature.

It may be the case that the projection optical unit 10 has different poses of the entrance pupil for the tangential beam path and for the sagittal beam path. In this case, an imaging element, for example an optical component part of the transfer optical unit, should be provided between the second facet mirror 22 and the reticle 7. Using this optical element, the different poses of the tangential entrance pupil and the sagittal entrance pupil may be taken into account.

In the arrangement of the components of the illumination optical unit 4 illustrated in FIG. 1, the second facet mirror 22 is arranged in an area conjugate to the entrance pupil of the projection optical unit 10. The first facet mirror 20 is arranged so as to be tilted in relation to the object plane 6. The first facet mirror 20 has a tilt with respect to an arrangement plane defined by the deflection mirror 19. The first facet mirror 20 has a tilt with respect to an arrangement plane defined by the second facet mirror 22.

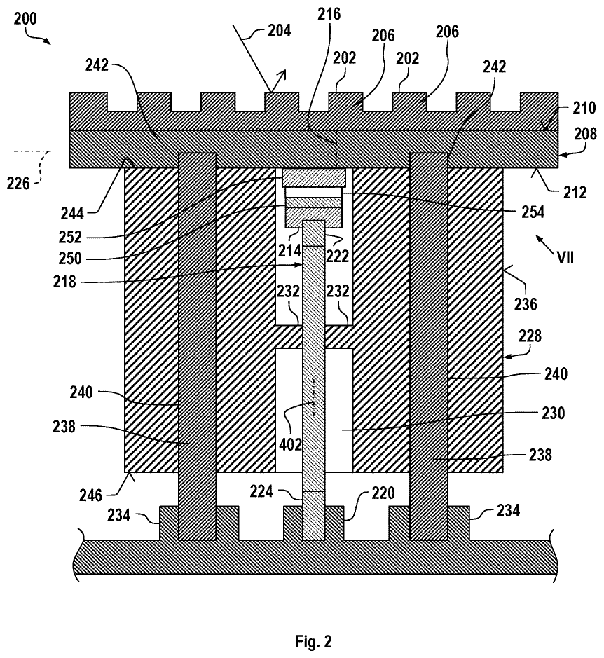

FIG. 2 shows a sectional view of one embodiment of an optical system 200 for a lithography apparatus or projection exposure apparatus 1, as shown for example in FIG. 1. Additionally, the optical system 200 in FIG. 2 can for example also be used in a DUV lithography apparatus.

The optical system 200 is for example a constituent part of the illumination optical unit 4 (FIG. 1) or may comprise it. For example, the optical system 200 may be a constituent part of or comprise one of the facet mirrors 20, 22.

The optical system 200 shown in the sectional view in FIG. 2 comprises a number of optical elements 202. By way of example, two of these optical elements have been provided with reference signs. In some embodiments, only a single optical element 202 may be provided, or more than two, for example more than 100, or more than 500 such optical elements 202 may be provided.

The optical elements 202 route radiation 204 through the lithography apparatus 1. The radiation 204 may be for example illumination radiation 16 from FIG. 1. The optical elements 202 may be in the form of lens elements or mirrors. For example, the optical elements 202 may be in the form of micromirrors, as in the exemplary embodiment according to FIG. 2. The mirrors or micromirrors may form the first or second facets 21, 23 from FIG. 1.

A or each optical element 202 may be assigned an actuator and/or sensor unit 206, which is only indicated schematically. A or each actuator and/or sensor unit 206 may comprise an actuator and/or a sensor, which is not illustrated in FIG. 2. The actuator may be configured to adjust the position of a corresponding optical element 202. The aim of this for example is to route the radiation 204 in a suitable way. The sensor may for example be in the form of a position sensor and be configured to detect a position of the assigned optical element 202. As an alternative or in addition, the sensor may be in the form of a temperature sensor.

The optical elements 202, like the actuator and/or sensor units 206, may be in the form of what are referred to as MEM systems (microelectromechamical systems). For example, the optical elements 202 and the actuator and/or sensor units 206 may be manufactured in integrated fashion. This means that they are produced for example on a substrate, for example a semiconductor substrate, such as silicon or gallium arsenide. For example, the sensors or actuators may have a largest dimension of 1 μm. For example, a diameter or a diagonal or another largest dimension of one of the micromirrors may be smaller than 5 mm or smaller than 1 mm.

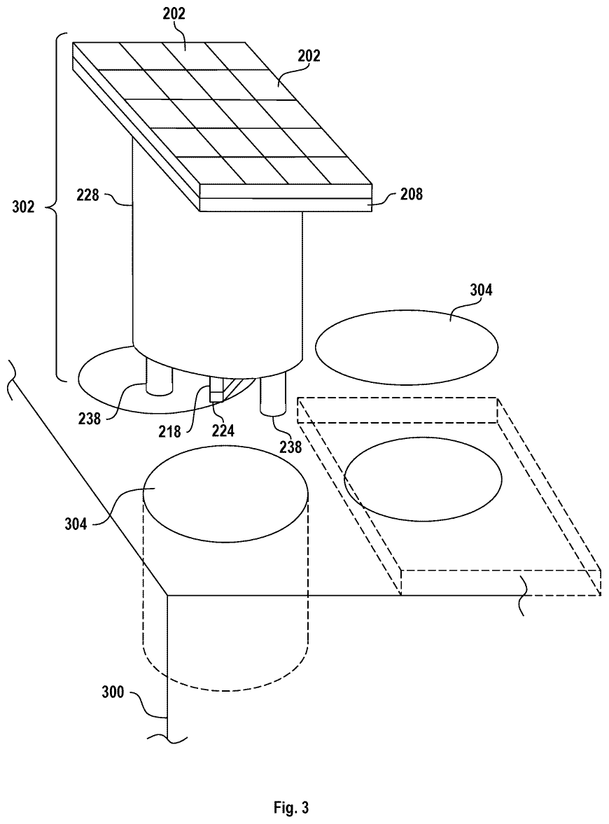

The optical system 200 further comprises a support apparatus 208. A (first) side 210 of the support apparatus 208 supports the one or more optical elements 202. In the present case, the side 210 is also referred to as the front side. The support apparatus 208 may even form the aforementioned substrate for providing the MEMS components (optical elements 202 and actuator and/or sensor units 206). The support apparatus 208 can be made of a ceramic, for example aluminum nitride. The support apparatus 208 may for example be flat. To this end, it may for example have the rectangular cross section with two long and two short sides shown in FIG. 2. As seen perpendicularly in relation to its main plane of extent 226, the support apparatus 208 may have a rectangular shape (as perspectively illustrated for example in FIG. 3), and round, oval or other shapes can also be considered. The one or more optical elements 202 may be fastened indirectly (for example via actuators or articulations, for example flexures), to the front side 210 of the support apparatus 208. As an alternative or in addition, the one or more optical elements 202 may be attached directly to the front side 210 of the support apparatus 208. For example, the one or more optical elements 202 may be adhesively bonded to the front side 210 (an electrical connection, i.e. linking up, of the optical elements 202 can be established via a conductive adhesive or soldering). In a further embodiment, the one or more optical elements 202 are applied in the form of a (if appropriate, respective) layer to the front side 210.

The support apparatus 208 also has a second side 212 (hereinafter also “back side”). The side 212 may be situated opposite the side 210 and thus the optical elements 202. On the side 212, the support apparatus 208 has a contact-connection device 214, i.e. the latter is mounted (for example adhesively bonded or soldered) and electrically contacted for example on the side 212. According to the exemplary embodiment as per FIG. 2, the contact-connection device 214 is arranged on a bridge 250. The bridge 250 extends above an active and/or passive component 252. The active and/or passive component is directly fastened on the back side 212 of the support apparatus 208.

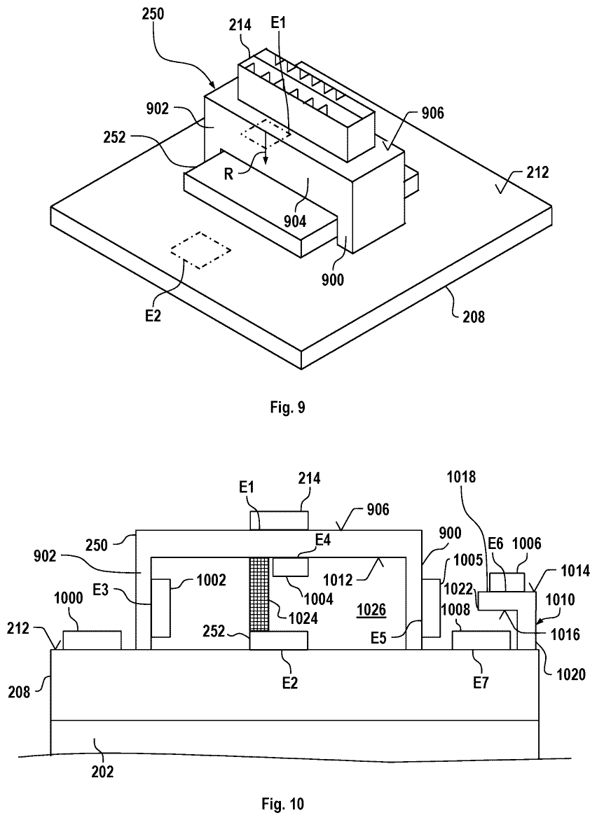

One possible structure for the contact-connection device 214, the bridge 250 and the active and/or passive component 252 is illustrated in FIG. 9. The view in that figure corresponds to a view of the aforementioned components obliquely from underneath in FIG. 2. The adjoining components in FIG. 2 are not shown in FIG. 9 for the sake of clarity.

The bridge 250 can be—like the support apparatus 208—made of a ceramic, for example aluminum nitride. The bridge 250 may be manufactured integrally, which is to say in one piece (i.e. in a primary forming step) and/or manufactured with the support apparatus 208 in integrated fashion. As an alternative, the bridge 250 may be mechanically and/or electrically connected to the support apparatus 208 via a joining method (soldering, using an electrically conductive adhesive, bonding, etc.). As a further alternative, the bridge 250 may be connected to the support apparatus 208 via a plug-in connector or another contact-connection device (in this case, the statements made in relation to the contact-connection device 214 apply, mutatis mutandis). In addition, an for example thermal bond may be provided.

The bridge 250 may have two opposite pillars 900, 902, which in FIG. 9 protrude upward from the back side 212 of the support apparatus 208. Between the pillars 900, 902 extends a spanning portion 904 of the bridge 250. Arranged on its top side 906 is an active and/or passive component, in this case in the form of the contact-connection device 214. The top side 906 is a side of the bridge 250 that faces away from the back side 212 of the support apparatus 208.

The spanning portion 904 of the bridge 250 spans an active and/or passive component, in this example a microprocessor 252. The microprocessor 252 is directly arranged on the side 212.

Generally speaking, the active or passive components 214, 252 are arranged in two different planes E1, E2. The planes E1, E2 may correspond to a respective bottom side of the respective component 214, 252. The “bottom” side means the side closest to the back side 212, i.e. the one with the smallest spacing therefrom. For example, the planes E1, E2 may run through a respective contact-connection plane of the components 214, 252. The plane E1 may for instance run through a contact-connection plane of the component 214 by the latter electrically contacting the bridge 250, i.e. the top side 906 thereof. Corresponding electrical contact points on the bottom side of the component 214 are not shown in FIG. 9. Similarly, the plane E2 may run through contact-connection points of the component 252 on its bottom side (the side facing toward the support apparatus 208, i.e. its back side 212). The corresponding contact-connection points are also not shown. The contact-connection points of the components 214, 252 may be formed by electrical contacts, contact pins, soldering points and/or SMD contact-connection points.

FIG. 9 also shows that the components 214, 252 overlap in a direction R perpendicular to the planes E1, E2. In other words, the components 214, 252 in FIG. 9 overlap as seen from top to bottom. In the exemplary embodiment according to FIG. 9, the planes E1, E2 are parallel to each other.

Returning to FIG. 2, also shown there is that the contact-connection device 214, the bridge 250 (like the cantilever arm 1010, which is yet to be explained later on and is not shown in FIG. 2) and/or the active and/or passive component 252 in some embodiments can be electrically connected to one or more of the actuator and/or sensor units 206. A corresponding conduction path is designated by way of example in FIG. 2 by the reference sign 216. The conduction path 216 may for example be in the form of a via (e.g. through-hole, blind and/or buried via, with a vacuum-tightness optionally being ensured nevertheless between the sides 210 and 212 of the support apparatus 208). In addition or as an alternative, the contact-connection device 214 may, however, also be electrically connected to other active and/or passive components. These components may be arranged on the sides 210 or 212 or elsewhere. The active or passive components comprise for example an integrated circuit, a processor, a microprocessor, an FPGA, an analog-to-digital converter, a digital-to-analog converter, a transistor, more particularly a MOSFET, a capacitor, a resistor and/or an inductor.

The optical system 200 further comprises a circuit board 218. The circuit board 218 can be electrically connected to the contact-connection device 214, FIG. 2 showing the electrically connected state. The electrical (and mechanical) connection can for example be detachable. Correspondingly, the circuit board 218 can be removed from the contact-connection device 214, for example for maintenance purposes.

The circuit board 218 connects the (first) contact-connection device 214 optionally to a further (second) contact-connection device 220 assigned to a current and/or voltage supply apparatus, which in all other respects is not shown in more detail. For example, one end 222 of the circuit board 218 may be electrically connected to the contact-connection device 214 and the other end 224 may, if appropriate, be electrically connected to the contact-connection device 220.

In the embodiment shown in FIG. 2, the contact-connection device 214 (the same also applies for the contact-connection device 220) may be in the form of a socket (see also FIG. 9, although in that figure the circuit board 218 is not illustrated for the sake of clarity). The end 222, which is for example in the form of an edge connector, of the circuit board 218 can be plugged (for example detachably) into the socket—FIG. 2 shows the plugged-in state.

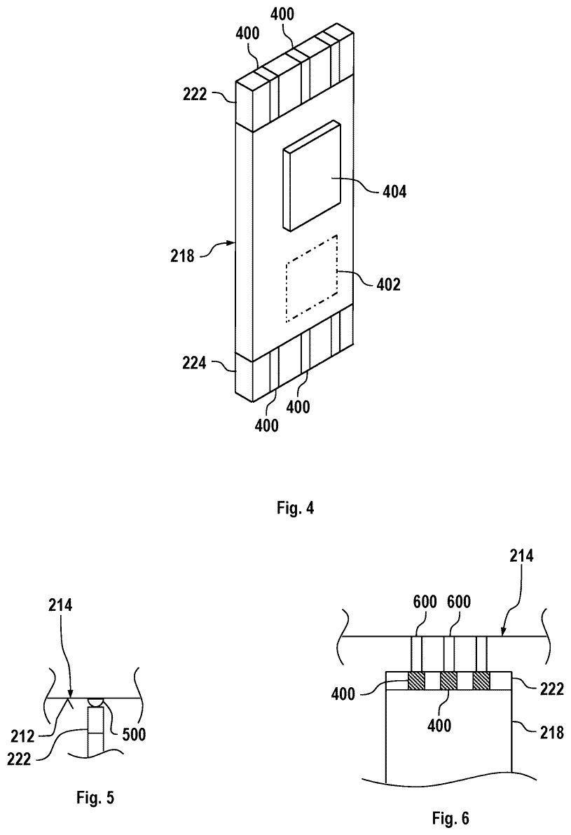

A correspondingly designed circuit board 218 is shown in FIG. 4, specifically in a perspective illustration. The circuit board 218 is for example made of an electrically insulating material with conductor tracks 400 adhering thereto or embedded therein. In the region of the ends 222, 224, the conductor tracks 400 are routed onto the edge of the circuit board 218 so that plug-in contacts are produced, which enter the socket-shaped contact-connection devices 214 and 220. The corresponding contacts may be hard-gold-plated, galvanized or provided with another coating, for example to prevent oxidation.

As FIG. 4 also shows, according to the exemplary embodiment the circuit board 218 is flat (in other words: is in the form of a plate) and is also—as seen in a direction perpendicular to its main plane of extent 402—rectangular.

Returning to FIG. 2, it is shown there that the main plane of extent 402 of the circuit board 218 extends perpendicularly in relation to the main plane of extent 226 of the support apparatus 208. In other embodiments, it is provided that only one portion of the circuit board 218 extends perpendicularly in relation to the support apparatus 208, i.e. its main plane of extent 226, and another portion of the circuit board is arranged at an angle, for example 45°, in relation to the support apparatus 208, i.e. its main plane of extent 226. In yet other embodiments, the circuit board 218 may have a curved profile, for example between its ends 222, 224. The circuit board 218 may be made of a rigid and/or flexible material. For example, it may be installed in a warped state.

In a variant which is not illustrated, the circuit board 218 is in the form of a bar, for example with a round, polygonal or oval cross section. Because the circuit board 218 in this case does not have a main plane of extent but only a main direction of extent, in this case the main direction of extent may point perpendicularly in relation to the main plane of extent 226 of the support apparatus 208.

Returning to FIG. 4, it is shown there that the circuit board 218 may have one or more passive and/or active components. To this end, FIG. 4 by way of example shows a microprocessor 404, which is electrically conductively connected to the conductor tracks 400 of the circuit board 218.

In FIG. 4, the microprocessor 404 (example of an electronic active component) is arranged on the circuit board 218. In the embodiment shown in section in FIG. 8, the microprocessor 404 is arranged in an interior space 800 in the circuit board 218. To this end, the interior space 800 is enclosed by an for example vacuum-tight housing 802. The vacuum-tight housing 802 is formed by the circuit board 218. For example, the circuit board 218 to this end has a layer structure with multiple layers 804, 806. The respective layer 804 forms an external layer, and the respective layer 806 forms an internal layer. The external layer 804 may for example be a heat dissipation layer and to this end be in the form of a metal layer. As an alternative, the external layer may be in the form of an insulator layer, for example an outgassing-resistant plastics film, or a lacquer. The internal layers 806 may be in the form of an alternating sequence of metal layers and insulating layers. The metal layers are for example made of copper and the insulating layers are made of a glass-fiber substrate or an epoxy resin. For example, a cutout may be made in one or more internal layers 806 to form the interior space 800, i.e. the vacuum-tight housing 802. In all other respects, in some embodiments the support apparatus 208 (and/or the bridge 250 or the cantilever arm 1010) itself may be in the form of a circuit board, with the features of the circuit board 218 that are described in the present case applying, mutatis mutandis, to the support apparatus 208.

In the following text, FIGS. 5 and 6 will be taken as a basis to describe two different further embodiments of the contact-connection device 214. These descriptions apply, mutatis mutandis, to the contact-connection device 220.

FIG. 5 schematically shows a detail of the end 222 of the circuit board 218, the short side thereof in FIG. 4 being illustrated. The end 222, or the contacts (conductor tracks 400) there, are in conductive contact with contact-connection islands, soldering contact points or landing pads 500 of the contact-connection device 214. The landing pads 500 are formed for example directly on the surface 906 (FIG. 9) of the bridge 250. In this case, the end 222 is not plugged into a socket. Instead, the electrical contact is established by moving the end 222, or the contacts (conductor tracks 400) there, against the landing pads 500, being held there and possibly being soldered there.

In the exemplary embodiment according to FIG. 6, the contact-connection device 214 is in the form of a one-piece interface (or another spring connector), which is also schematically illustrated in FIG. 9. The one-piece interface (or other spring connector) comprises a multiplicity of springs or spring contact pins 600 which resiliently bear, establishing electrical contact, against the contacts formed by the conductor tracks 400 at the end 222 of the circuit board 218. FIG. 6 shows the long side of the circuit board 218 from FIG. 4. In some embodiments, the springs or spring contact pins 600 may be attached to the circuit board 218 and contact its conductor tracks 400. In this case, in the installed state of the circuit board 218, the springs or spring contact pins 600 may bear, establishing electrical contact, for example against landing pads (which may for example be hard-gold-plated) formed on the top side 906.

Returning to FIG. 2, it is also shown there that a housing apparatus 228 is arranged on the back side 212. The housing apparatus 228 may be provided with one or more of the functions described below.

Firstly, it may mechanically take up holding forces resulting from the attachment of the support apparatus 208. For example, it may transfer these holding forces to a holding apparatus 300, which is shown in perspective in FIG. 3.

Another function of the housing function 228 may be to receive and protect the circuit board 218 at least partly in its interior space 230. The circuit board 218 may extend for example from its one end 222 to its other end 224 through the interior space 230. The housing apparatus may have brace elements 232, which brace the circuit board 218 within the cavity 230. The brace elements 232 may extend perpendicularly in relation to the main plane of extent 402 of the circuit board 218.

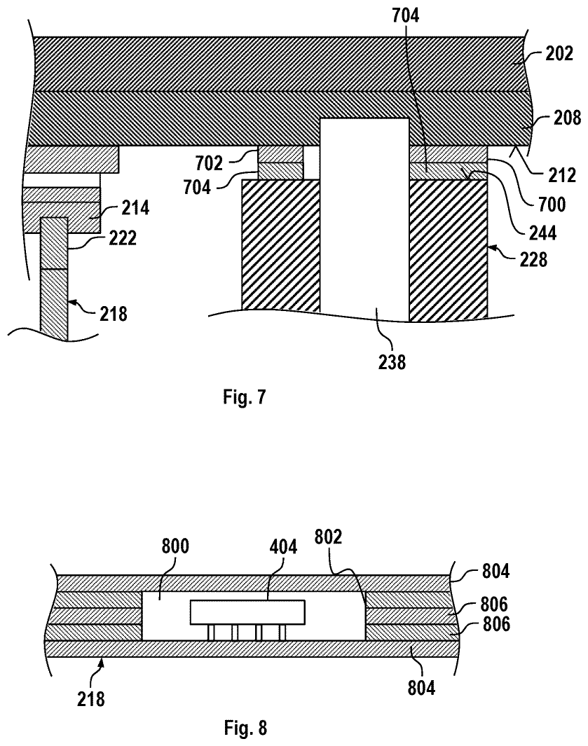

Yet another function of the housing apparatus 228 may be to carry heat from the support apparatus 208 to a cooling apparatus. In FIG. 2, the cooling apparatus is represented by way of example by two heat sinks 234. The heat to be discharged results for example from the non-reflected, and therefore absorbed portion of the radiation 204. For example in the case of EUV light, only some of the incident light power is reflected by the optical elements 202. The rest is dissipated in the form of heat. In addition or as an alternative, the actuator/sensor units 206 can however also generate heat, which is dissipated. The active and passive components mentioned above and hereinafter, for instance the microprocessor 404 (FIG. 4) on the circuit board 218 or electronic components 252, 700, 702 (as will be explained later on in more detail in conjunction with FIG. 7) arranged on the back side 212 of the support apparatus 208, can also generate heat, which is dissipated at least partially via the housing apparatus 228. There are various possible ways of doing this. It is possible, for example—this is not shown in FIG. 2—to bathe the lateral surface 236 or another outer surface of the housing apparatus 228 in a coolant, for example air or water. For example, the heat can be discharged from the lateral surface 236 via an air gap to the cooler and/or to a cooling mechanism of the holding apparatus 300 (FIG. 3).

According to a variant shown in FIG. 2, the housing apparatus 228 has one or more heat tubes 238 (for example in the form of a heat pipe). They extend through openings 240 in the housing 228. The openings 240 may for example be in the form of through holes, ducts or the like. The heat tubes 238 extend from the support apparatus 208, where they may be arranged in pockets 242 (as shown), to the heat sinks 234, to which they are thermally conductively coupled.

The housing apparatus 228 may be made of a thermally conductive material, for example copper or aluminum and alloys thereof. The housing apparatus 228 may also have a cylindrical shape, as shown in perspective in FIG. 3. According to the exemplary embodiment, it is a circular cylinder. As an alternative, the cylindrical shape may have a rectangular, oval or other cross section.

Returning to FIG. 2, it is shown there that one end face 244 of the cylindrical shape is connected—in this exemplary embodiment directly-to the back side 212 of the support apparatus 208. The opposite end face 246 of the cylindrical shape, i.e. of the housing apparatus 228, can bear against a mating surface, not shown, of the holding apparatus 300 from FIG. 3. For example, the end side 246 of the housing apparatus 228 may be screwed to the holding apparatus 300. This is the case for example in the assembled state shown (in dashed lines) on the right in FIG. 3.

The top left of FIG. 3 shows a premounted unit 302. The premounted unit 302 comprises—from FIG. 2—the optical elements 202, the support apparatus 208, the housing apparatus 228, the circuit board 218 and the heat tube 238. The thus premounted unit 302 is plugged into a receptacle 304 of the holding apparatus 300. For example, the receptacle 304 may have a circular-cylindrical opening corresponding to the circular-cylindrical shape of the housing apparatus 228. FIG. 3 shows the inserted, i.e. installed, state in dashed lines on the right (as already mentioned above). In the installed state, the housing apparatus 228 is (partially or completely) fitted for example in the receptacle 304. The optical elements 202, by contrast, are freely accessible from the top (if appropriate, in the vacuum). It may be provided that the electrical connection, possibly also like the thermal-coupling connection, is already established by the plugging-in operation. This means that, by plugging the premounted unit 302 into the receptacle 304, the lower end 224 of the circuit board 208 is plugged into the contact-connection device 220 (FIG. 2) at a lower end of the receptacle 304. Correspondingly, at the lower end of the receptacle 304 the heat tubes 238 also establish a thermally conductive connection with corresponding heat sinks 234.

As FIG. 3 further shows, the holding apparatus 300 may have multiple receptacles 304. Correspondingly, multiple premounted units 302, for example more than five, more than ten or more than 100 units 302, can be mounted in the holding apparatus 300. For maintenance purposes, the devices 302 can also be disassembled again individually. For this, they are for example upwardly taken out of the respective receptacle 304. After that, for example the circuit board 218 at its downwardly projecting free end 224 can be taken out of its electrical connection with the contact-connection device 214 (FIG. 2). This can be done for example whenever one of the conductor tracks 400 (FIG. 4) or the microprocessor 404 (FIG. 4) or another active and/or passive component of the circuit board 218 is thought to be defective.

FIG. 7 illustrates a magnified view VII from FIG. 2 of a further variant. In this variant, the housing apparatus 224 is at least partially not directly fastened to the back side 212 of the support apparatus 208. Rather, on the back side 212 one or more—in this example two—passive and/or active components 700, 702 are provided. The statements made above regarding active and passive components apply. The components 700, 702 may be connected for example electrically to the actuator and/or sensor units 206. Between the end face 244 of the housing apparatus 228 and the components 700, 702 there is a gap, which may be filled with a thermally conductive filler material 704 (referred to as TIM, for example a thermally conductive paste), as illustrated in FIG. 7, or provided in the form of an air or vacuum gap. Besides the heat conduction function, the thermally conductive filler material 704 may also have a tolerance compensation function. The tolerance compensation in this case takes place for example between the housing apparatus 228 and the back side 212 of the support apparatus 208.

In other embodiments, no thermally conductive filler material is provided, and the end face 244 bears directly against the components 700, 702. In some variants, for example the brace elements 232 or other portions of the housing apparatus 228 can also thermally conductively bear against the microprocessor 404 or another passive and/or active component. This can in turn be effected using a thermally conductive filler material.

FIG. 7 therefore illustrates an example of an indirect arrangement of the housing apparatus 228 or at least a part thereof on the back side 212 of the support apparatus 208. In some variants, the housing apparatus 228 is also not arranged on the back side 212, but on another portion of the support apparatus 208.

FIG. 10 illustrates, for a multiplicity of possibly different active and/or passive components 1000-1008, how they can be arranged on the back side 212 of the support apparatus 208, on or underneath a bridge 250 and on or underneath a cantilever arm 1010. FIG. 10 also illustrates the arrangement, on and underneath the bridge 250, of the components 214, 252 already known from FIG. 9. In some exemplary embodiments, one or more of these components 214, 252, 1000-1008 may be provided in different combinations. The planes of the respective active and/or passive components in which the latter are arranged are denoted E1-E7. They correspond to the respective bottom side of each component 214, 252, 1000-1008.

The active and/or passive component 1000 is arranged in the plane E2, i.e. on the back side 212. It is not underneath the bridge 250 or the cantilever arm 1010 but is laterally offset next to it.

The active and/or passive component 1002 is arranged in a plane E3. The plane E3 is perpendicular to the planes of symmetry E2 and E1. However, the plane E3 could also be at another angle to the plane E2. For example, “perpendicular(ly)” also includes deviations of, for example, up to 20°, up to 10° or up to 5° from the exact perpendicular. The active and/or passive component 1002 is arranged on the inner side of the pillar 902 of the bridge 250.

The active and/or passive component 1004 is arranged in a plane E4 which is parallel to and offset from the planes E1 and E2. The active and/or passive component 1004 is arranged on a bottom side 1012 of the bridge 250, or of the spanning portion 904. The bottom side 1012 faces toward the back side 212 of the support apparatus 208.

The active and/or passive component 1005 is arranged in a plane E5 which can also extend perpendicularly in relation to or at an angle to the planes E1, E2 and/or E4. The active and/or passive component 1005 is arranged on an outer side of the bridge 250, or of the pillar 900.

The active and/or passive component 1006 is arranged on a top side 1014 of the cantilever arm 1010. It is arranged in a plane E6 which is parallel to (and possibly offset from) the planes E1, E2 and/or E4. The top side 1014 faces away from the back side 212. Similarly, the active and/or passive component 1006 may be arranged on the bottom side 1016 of the cantilever arm 1010, or a further active and/or passive component (not shown) could be arranged there. The cantilever arm 1010 may be composed of a self-supporting portion 1018 and a foot portion 1020, which connects the self-supporting portion 1018 on its one side to the support apparatus 208, i.e to the back side 212. The free end 1022 of the cantilever arm 1010 is free and not connected to the back side 212. The active and/or passive component 1006 is fastened to the self-supporting portion 1018 of the cantilever arm 1010, but similarly could be arranged on the inner or outer side of the foot portion 1020. In this case, the corresponding plane E6 would be perpendicular to the planes E1 and E2.

Furthermore, FIG. 10 illustrates the use of a thermally conductive material 1024 (referred to as TIM, for example thermally conductive paste). It is provided in a gap 254, visible in FIG. 2, between the component 252 and the bridge 250 and ensures an improved transfer of heat between them. In some embodiments, the region 1026 between the bridge 250 and the support apparatus 208, i.e. the side 212, may be partially or completely filled, for example potted, with the thermally conductive material 1024. In addition or as an alternative, the bridge 250 may be thermally attached to the housing apparatus 228 and/or at least one of the heat tubes 238 via a thermally conductive material (not shown). It is equally possible for the cantilever arm 1010—like the bridge 250—to also be thermally conductively connected to the component 1008 and/or another of the aforementioned objects (support apparatus 208, housing apparatus 228 and/or heat tube 238) via a thermally conductive material (not shown).

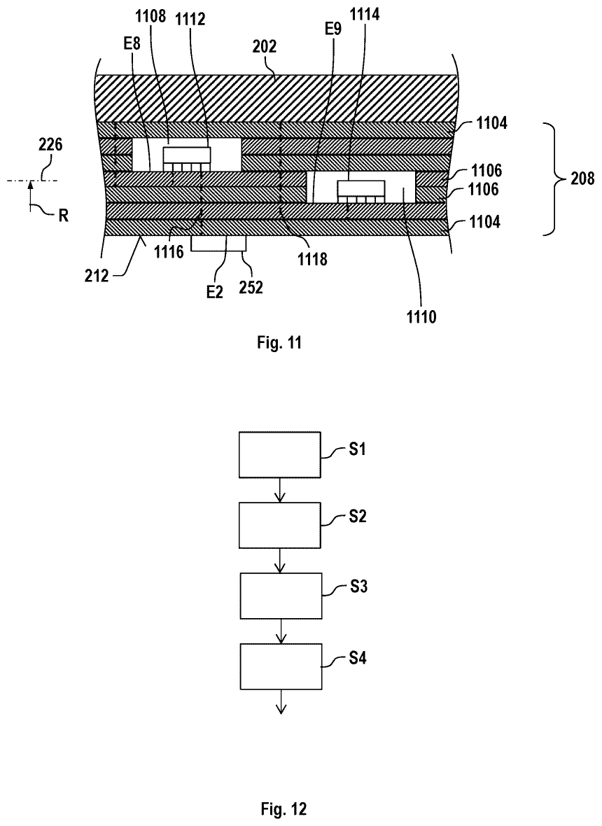

FIG. 11 shows a partial section through the support apparatus 208, for example according to one of the preceding exemplary embodiments. For the sake of better understanding, the optical elements 202 and the active and/or passive component 252 are also (partially) shown. The rest of the components, which may be provided according to the previous figures, are not shown in FIG. 11 for the sake of a better overview.

The support apparatus 208 may be made of a composite material, as already explained for example in conjunction with FIG. 8. For example, the support apparatus 208 may comprise a layer structure with external layers 1104 and internal layers 1106. The explanations given in relation to FIG. 8 as regards the layers 804, 806 apply, mutatis mutandis.

Provided within the support apparatus 208 are by way of example two interior spaces 1108, 1110, each of which contains an active and/or passive component 1112, 1114. The interior spaces 1108, 1110 are in the form of closed housings that for example can be vacuum-tight. The active and/or passive component 1112 is arranged in a plane E8 and the active and/or passive component 1114 is arranged in a plane E9 which—purely by way of example—are parallel to one another and offset, i.e. spaced apart, from one another in a direction perpendicular to the main plane of extent 226 of the support apparatus 208. The active and/or passive components 1112, 1114 may be connected by way of electrical contact-connections (vias), two of which are designated by the reference signs 1116, 1118 by way of example, to an actuator and/or sensor unit which is assigned to one of the optical elements 202 (see conduction path 1118), and/or to the active and/or passive component 252 arranged on the back side 212.

In the example in FIG. 11, the active and/or passive components 252 and 1112 overlap in the direction R.

It is also possible for one or more of the interior spaces 1108, 1110 to be partially or completely filled, for example potted, with a thermally conductive material (referred to as TIM; not shown). The same applies in all other respects for the interior space 800 in FIG. 8.

FIG. 12 illustrates a flow diagram of a method for producing an optical system 200, as described in the preceding figures.

In a step S1, one or more optical elements 202 are mechanically connected to a support apparatus 208. One or respective actuator/sensor units 206 assigned to the optical elements 202 may be electrically connected to the support apparatus 208, i.e. to contact-connections formed thereon or therein. The housing apparatus 228 may also be attached to the support apparatus 208.

In a step S2, at least two active and/or passive components 214, 252, 700, 702, 1000, 1002, 1004, 1005, 1006, 1008, 1112, 1114 are arranged in two different planes E1 to E9 on or in the support apparatus 208.

In an optionally provided step S3, a circuit board 218 is electrically conductively connected to a contact-connection device 214.

The unit 302 premounted in this way is optionally mounted on a holding apparatus 300 in a step S4.

Although the present disclosure has been described using exemplary embodiments, it can be modified in a variety of ways.

### LIST OF REFERENCE SYMBOLS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
200 Optical system
202 Optical element
204 Radiation
206 Actuator unit and/or sensor unit
208 Support apparatus
210 Side
212 Side
214 Contact-connection device
216 Conduction path
218 Circuit board
220 Contact-connection device
222 End
224 End
226 Main plane of extent
228 Housing apparatus
230 Interior space
232 Brace element
234 Heat sink
236 Lateral surface
238 Heat tube
240 Opening
242 Pocket
244 End face
246 End face
250 Bridge
252 Component
254 Gap
300 Holding apparatus
302 Pre-mounted unit
304 Receptacle
400 Conductor track
402 Main plane of extent
404 Microprocessor
500 Solder contact point
600 Spring
700 Component
702 Component
704 Filler material
800 Interior space
802 Housing
804 Layer
806 Layer
900 Pillar
902 Pillar
904 Spanning portion
906 Top side
1000 Component
1002 Component
1004 Component
1005 Component
1006 Component
1008 Component
1010 Cantilever arm
1012 Bottom side
1014 Top side
1016 Bottom side
1018 Self-supporting portion
1020 Foot portion
1022 Free end
1024 Thermally conductive material
1026 Region
1104 Layer
1106 Layer
1108 Interior space
1110 Interior space
1112 Component
1114 Component
1116 Contact connection
1118 Contact connection
M1 Mirror
M2 Mirror
M3 Mirror
M4 Mirror
M5 Mirror
M6 Mirror
R Direction
E1 to E9 Planes
S1 to S4 Steps

What is claimed is:

1. An optical system, comprising:
a number of optical elements configured to guide radiation;
a support apparatus supporting the optical elements; and
a plurality of active and/or passive components arranged in first and second planes on the support apparatus,
wherein:
the first plane is different from the second plane;
the first and second planes run through a respective contact-connection plane of the active and/or passive components, and
the active and/or passive components are arranged on a first side of the support apparatus.

2. The optical system of claim 1, wherein:
the first and second planes are parallel to one another; and/or
at least two of the active and/or passive components overlap.

3. The optical system of claim 1, wherein the number of optical elements is arranged on a second side of the support apparatus different from the first side of the support apparatus.

4. The optical system of claim 1, wherein:
a bridge is arranged on the first side of the support apparatus, and a subset of the active and/or passive components is arranged on or underneath the bridge; or
a cantilever arm is arranged on the first side of the support apparatus, and a subset of the active and/or passive components is arranged on or underneath the cantilever arm.

5. The system of claim 1, wherein:
a bridge is arranged on the first side of the support apparatus, and a subset of the active and/or passive components is arranged on a top side of the bridge; or
a bridge is arranged on the first side of the support apparatus, and a subset of the active and/or passive components is arranged on a bottom side of the bridge;
a cantilever arm is arranged on the first side of the support apparatus, and a subset of the active and/or passive components is arranged on a top side of the bridge; and/or
a cantilever arm is arranged on the first side of the support apparatus, and a subset of the active and/or passive components is arranged on a bottom side of the bridge.

6. The optical system of claim 1, wherein:
a bridge is arranged on the first side of the support apparatus, a first active and/or passive component is arranged on the bridge, and a second active and/or passive component is arranged underneath the bridge; or
a cantilever arm is arranged on the first side of the support apparatus, a first active and/or passive component is arranged on the cantilever arm, and the second active and/or passive component is arranged underneath the cantilever arm.

7. The optical system of claim 1, wherein the support apparatus comprises a composite material defining a housing, and at least one of the active and/or passive components is arranged in the housing.

8. The optical system of claim 1, wherein:
a first subset of the active and/or passive components is arranged on the first side of the support apparatus;
a second subset of the active and/or passive components is arranged on or underneath a bridge arranged on the first side of the support apparatus, or the second subset of the active and/or passive components is on or underneath a cantilever arm arranged on the first side of the support apparatus; and
a third subset of the active and/or passive components is arranged in an interior space of the support apparatus.

9. The optical system of claim 1, wherein:
a bridge is arranged on the first side of the support apparatus, a subset of the active and/or passive components is arranged on or underneath the bridge, and the bridge comprises a ceramic; or
a cantilever arm is arranged on the first side of the support apparatus, a subset of the active and/or passive components is arranged on or underneath the cantilever arm, and the cantilever arm comprises a ceramic.

10. The optical system of claim 1, wherein the active and/or passive components comprise an integrated circuit, a processor, a microprocessor, an FPGA, an analog-to-digital converter, a digital-to-analog converter, a transistor, a capacitor, a resistor, an inductor, and/or a contact-connection device.

11. The optical system of claim 10, wherein the number of optical elements is arranged on a second side of the support apparatus different from the first side of the support apparatus.

12. The optical system of claim 10, wherein:
a bridge is arranged on the first side of the support apparatus, and a subset of the active and/or passive components is arranged on or underneath the bridge; or
a cantilever arm is arranged on the first side of the support apparatus, and a subset of the active and/or passive components is arranged on or underneath the cantilever arm.

13. The optical system of claim 1, wherein:
the active and/or passive components comprise a contact-connection device electrically connected to a circuit board; and
the contact-connection device is arranged on a bridge arranged on the first side of the support apparatus, or the contact-connection device is arranged on a cantilever arm arranged on the first side of the support apparatus.

14. The optical system of claim 10, further comprising a housing apparatus through which the circuit board is routed, wherein the housing apparatus is thermally conductively connected to at least one of the active and/or passive components.

15. The optical system of claim 14, further comprising a thermally conductive material in a gap between the housing apparatus and the at least one of the active and/or passive components.

16. The optical system of claim 15, wherein the thermally conductive material comprises a thermally conductive paste.

17. The optical system of claim 1, wherein the optical system is a lithography illumination optical unit or a lithography projection optical unit.

18. An apparatus, comprising:
an optical system according to claim 1,
wherein the apparatus is a lithography apparatus.

19. The apparatus of claim 18, wherein the apparatus is an EUV lithography apparatus or a DUV lithography apparatus.

20. An optical system, comprising:
a number of optical elements configured to guide radiation;
a support apparatus supporting the optical elements; and
a plurality of active and/or passive components arranged in first and second planes in the support apparatus,
wherein:
the first plane is different from the second plane;
a subset of the active and/or passive components is arranged in a closed interior space of the support apparatus; and
the closed interior space of the support apparatus is a closed chamber or a closed housing.
